(19) United States
(12) Patent Application Publication
(10) Pub. No.: US 2022/0085094 A1
(43) Pub. Date: Mar. 17, 2022

(54) IMAGING SYSTEMS, PHOTO-DETECTORS AND PHOTODIODES

(71) Applicants: Beijing BOE Technology Development Co., Ltd., Beijing (CN); BOE Technology Group Co., Ltd., Beijing (CN)

(72) Inventor: Tuo SUN, Beijing (CN)

(21) Appl. No.: 17/459,798

(22) Filed: Aug. 27, 2021

(30) Foreign Application Priority Data
Sep. 17, 2020 (CN) 202010982805.6

(51) Int. Cl. H01L 27/146

(52) U.S. Cl. CPC H01L 27/14643; H01L 27/14612; H01L 27/14607

(57) ABSTRACT

Provided are an imaging system, a photo-detector and a photodiode. In an embodiment, the photodiode includes an electrode layer and a semiconductor layer. The electrode layer includes a first electrode and a second electrode surrounding the first electrode. An annular region between an orthogonal projection of the second electrode and an orthogonal projection of the first electrode on the substrate has an inner edge and an outer edge. The inner edge is polygonal or circular, and an included angle of any two adjacent sides of the inner edge is an obtuse angle when the inner edge is polygonal. The outer edge of the annular region is polygonal or circular, and an included angle of any two adjacent sides of the outer edge is an obtuse angle when the outer edge is polygonal. The semiconductor layer is disposed at a side of the electrode layer away from the substrate.

### CROSS REFERENCE TO RELATED APPLICATIONS

This application claims priority to Chinese Patent Application No. 2020109828056 entitled “IMAGING SYSTEM, PHOTO-DETECTOR AND PHOTODIODE” filed on Sep. 17, 2020, the entire content of which is incorporated herein by reference.

### TECHNICAL FIELD

The present disclosure relates to the field of detection technologies, and in particular to an imaging system, a photo-detector, and a photodiode.

### BACKGROUND

Along with social development and continuous progress of scientific technologies, photo-detectors are gradually and widely applied in the medical imaging field and the like.

### SUMMARY

An aspect of the present application provides a photodiode, including:

an electrode layer, including a first electrode and a second electrode surrounding the first electrode, wherein an annular region between an orthogonal projection of the second electrode on a substrate and an orthogonal projection of the first electrode on the substrate has an inner edge and an outer edge; the inner edge of the annular region is polygonal or circular, and an included angle of any two adjacent sides of the inner edge of the annular region is an obtuse angle when the inner edge of the annular region is polygonal; the outer edge of the annular region is polygonal or circular, and an included angle of any two adjacent sides of the outer edge of the annular region is an obtuse angle when the outer edge of the annular region is polygonal; and

a semiconductor layer, disposed at a side of the electrode layer away from the substrate.

Optionally, the inner edge and the outer edge of the annular region both are polygonal, and the sides of the inner edge of the annular region and the sides of the outer edge of the annular region are identical in number and are parallel one-to-one.

Optionally, the inner edge of the annular region is polygonal, and a first rounded corner is formed at a connection of two adjacent sides of the inner edge of the annular region; and/or,

the outer edge of the annular region is polygonal, and a second rounded corner is formed at a connection of two adjacent sides of the outer edge of the annular region.

Optionally, a connection of two adjacent sides of the inner edge of the annular region has a first rounded corner, a connection of two sides of the outer edge of the annular region parallel with the two adjacent sides of the inner edge of the annular region has a second rounded corner, and

a center of circle of the first rounded corner is overlapped with a center of circle of the second rounded corner.

Optionally, the inner edge and the outer edge of the annular region both are hexagonal.

Optionally, an outer edge of the orthogonal projection of the second electrode on the substrate is polygonal and an included angle of any two adjacent sides is an obtuse angle; or,

the outer edge of the orthogonal projection of the second electrode on the substrate is circular.

Optionally, the outer edge of the orthogonal projection of the second electrode on the substrate is polygonal and a third rounded corner is formed at a connection of at least two adjacent sides of the outer edge of the orthogonal projection of the second electrode on the substrate.

Optionally, the outer edge of the orthogonal projection of the second electrode on the substrate is polygonal, the outer edge of the annular region is polygonal, and the sides of the outer edge of the orthogonal projection of the second electrode on the substrate and the sides of the outer edge of the annular region are identical in number and are parallel one-to-one.

Optionally, the outer edge of the orthogonal projection of the second electrode on the substrate is hexagonal.

An aspect of the present application provides a photo-detector, including:

a substrate; and

a photodiode, including:
an electrode layer, disposed on the substrate and including a first electrode and a second electrode surrounding the first electrode, wherein an annular region between an orthogonal projection of the second electrode on the substrate and an orthogonal projection of the first electrode on the substrate has an inner edge and an outer edge; the inner edge of the annular region is polygonal or circular, and an included angle of any two adjacent sides of the inner edge of the annular region is an obtuse angle when the inner edge of the annular region is polygonal; the outer edge of the annular region is polygonal or circular, and an included angle of any two adjacent sides of the outer edge of the annular region is an obtuse angle when the outer edge of the annular region is polygonal; and
a semiconductor layer, disposed at a side of the electrode layer away from the substrate.

Optionally, the photodiode includes a plurality of photodiodes and second electrodes of any two adjacent photodiodes are in electrical connection.

Optionally, the photodiode includes a plurality of photodiodes and the semi-conductor layers of the plurality of photodiodes are of an integral structure.

Optionally, the photo-detector further includes:

a reading transistor, disposed on the substrate, wherein the electrode layer is disposed at a side of the reading transistor away from the substrate, and the first electrode is in electrical connection with a source electrode or a drain electrode of the reading transistor.

Optionally, the photodiode includes a plurality of photodiodes, and orthogonal projections of the second electrodes of the plurality of photodiodes on the substrate are arranged like honeycomb.

Optionally, the inner edge and the outer edge of the annular region both are polygonal, and the sides of the inner edge of the annular region and the sides of the outer edge of the annular region are identical in number and are parallel one-to-one.

Optionally, the inner edge of the annular region is polygonal and a first rounded corner is formed at a connection of two adjacent sides of the inner edge of the annular region; and/or,

the outer edge of the annular region is polygonal, and a second rounded corner is formed at a connection of two adjacent sides of the outer edge of the annular region.

Optionally, a connection of two adjacent sides of the inner edge of the annular region has a first rounded corner, a connection of two sides of the outer edge of the annular region parallel with the two adjacent sides of the inner edge of the annular region has a second rounded corner, and

a center of circle of the first rounded corner is overlapped with a center of circle of the second rounded corner.

Optionally, an outer edge of the orthogonal projection of the second electrode on the substrate is polygonal and an included angle of any two adjacent sides is an obtuse angle; or,

the outer edge of the orthogonal projection of the second electrode on the substrate is circular.

Optionally, the outer edge of the orthogonal projection of the second electrode on the substrate is polygonal, and a third rounded corner is formed at a connection of at least two adjacent sides of the outer edge of the orthogonal projection of the second electrode on the substrate.

An aspect of the present application provides an imaging system, including at least one photo-detector each including:

a substrate; and

a photodiode, including:
an electrode layer, disposed on the substrate and including a first electrode and a second electrode surrounding the first electrode, wherein an annular region between an orthogonal projection of the second electrode on the substrate and an orthogonal projection of the first electrode on the substrate has an inner edge and an outer edge; the inner edge of the annular region is polygonal or circular, and an included angle of any two adjacent sides of the inner edge of the annular region is an obtuse angle when the inner edge of the annular region is polygonal; the outer edge of the annular region is polygonal or circular, and an included angle of any two adjacent sides of the outer edge of the annular region is an obtuse angle when the outer edge of the annular region is polygonal; and
a semiconductor layer, disposed at a side of the electrode layer away from the substrate.

### BRIEF DESCRIPTION OF DRAWINGS

FIG. 1 is a schematic diagram of a photo-detector according to one or more embodiments of the present disclosure.

FIG. 2 is a schematic diagram of a first electrode and a second electrode according to one or more embodiments of the present disclosure.

FIG. 3 is a schematic diagram of an annular region according to one or more embodiments of the present disclosure.

FIG. 4 is another schematic diagram of a first electrode and a second electrode according to one or more embodiments of the present disclosure.

FIG. 5 is a schematic diagram of arrangement of a plurality of photodiodes according to an embodiment of the present disclosure.

FIG. 6 is a schematic diagram of connection of first electrodes and reading transistors according to an embodiment of the present disclosure.

FIG. 7 is another schematic diagram of a first electrode and a second electrode according to one or more embodiments of the present disclosure.

FIG. 8 is a schematic diagram of a first electrode and a second electrode in the related art.

### DETAILED DESCRIPTION

Embodiments will be described in detail herein, with the illustrations thereof represented in the drawings. When the following descriptions involve the drawings, like numerals in different drawings refer to like or similar elements unless otherwise indicated. The embodiments described in the following examples do not represent all embodiments consistent with the present disclosure. Rather, they are merely examples of apparatuses and methods consistent with some aspects of the present disclosure as detailed in the appended claims.

Terms used herein are used to only describe a particular embodiment rather than limit the present disclosure. Unless otherwise defined, technical terms or scientific terms used in the present disclosure should have general meanings that can be understood by ordinary persons of skill in the art. “First” “second” and the like used in the specification and claims do not represent any sequence, quantity or importance, but distinguish different components. Similarly, “one” or “a” and the like do not represent quantity limitation but represent at least one. “Multiple” or “a plurality” represents two or more. Unless otherwise stated, the words such as “front”, “rear”, “lower” and/or “upper” are used only for ease of descriptions rather than limited to one position or a spatial orientation. Unless otherwise stated, “include” or “contain” or the like is intended to refer to that an element or object appearing before “include” or “contain” covers an element or object or its equivalents listed after “include” or “contain” and does not preclude other elements or objects. “Connect” or “connect with” or the like is not limited to physical or mechanical connection but includes direct or indirect electrical connection. The singular forms such as “a”, ‘said”, and “the” used in the present disclosure and the appended claims are also intended to include multiple, unless the context clearly indicates otherwise. It is also to be understood that the term “and/or” as used herein refers to any or all possible combinations that include one or more associated listed items.

A photo-detector includes a substrate and a photodiode disposed on the substrate. The photodiode includes a semiconductor layer. The semiconductor layer is capable of converting optical signals into electrical signals and sending the electrical signals to a signal processing circuit. The signal processing circuit may generate an image based on the electrical signals. In the related art, an inner edge and an outer edge of an annular region between a projection of a first electrode and a projection of a second electrode are square, and the photodiode has a low photo-electrical conversion efficiency, thus affecting the detection effect of the photo-detector.

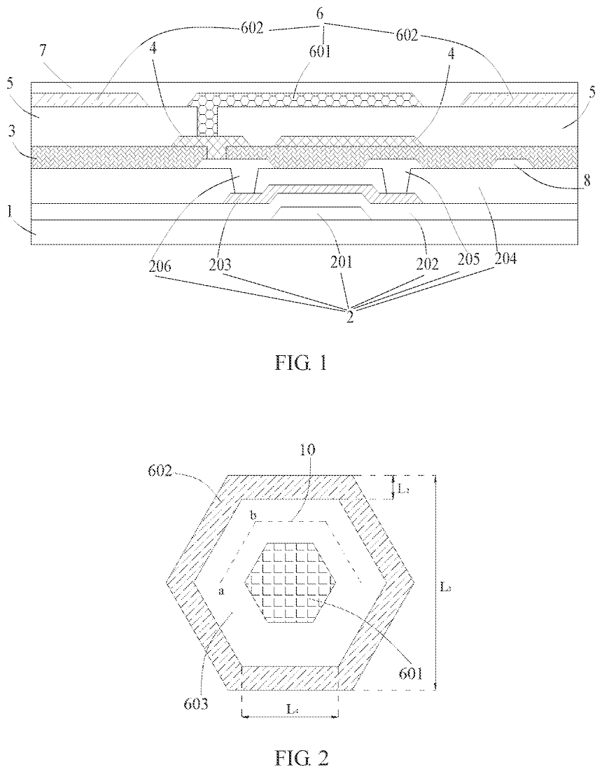

The present disclosure provides a photodiode which is applicable in a photo-detector. As shown in FIGS. 1 and 2, the photo-detector includes a substrate 1. The photodiode includes a semiconductor layer 7 and an electrode layer 6.

The electrode layer 6 includes a first electrode 601 and a second electrode 602 surrounding the first electrode 601. An annular region 603 between an orthogonal projection of the second electrode 602 on the substrate 1 and an orthogonal projection of the first electrode 601 on the substrate 1 has an inner edge and an outer edge. The inner edge of the annular region 603 is polygonal or circular. An included angle of any two adjacent sides of the inner edge of the annular region 603 is an obtuse angle in a case that the inner edge of the annular region 603 is polygonal. The outer edge of the annular region 603 is polygonal or circular. An included angle of any two adjacent sides of the outer edge of the annular region 603 is an obtuse angle in a case that the outer edge of the annular region 603 is polygonal. The semiconductor layer 7 is disposed at a side of the electrode layer 6 away from the substrate 1.

In the photodiode according to the embodiments of the present disclosure, the second electrode 602 surrounds the first electrode 601, the inner edge and the outer edge of the annular region between the orthogonal projection of the second electrode 602 on the substrate 1 and the orthogonal projection of the first electrode 601 on the substrate 1 are polygonal or circular, and the included angle of any two adjacent sides of the inner edge and the outer edge of the annular region 603 is an obtuse angle in a case that the inner edge and the outer edge of the annular region 603 are polygonal. In this way, a distance between the inner edge and the outer edge of the annular region 603 is more uniform and thus an electric field intensity between the first electrode 601 and the second electrode 602 is more uniform. Therefore, photo-generated carriers in the semiconductor layer 7 can be driven and effectively transferred, thereby improving the photo-electrical conversion efficiency.

Various aspects of the photodiode according to the embodiments of the present disclosure will be detailed below.

As shown in FIG. 1, the semiconductor layer 7 of the photodiode may generate photo-generated carriers under light irradiation. Therefore, the semiconductor layer 7 may convert optical signals into electrical signals. The semiconductor layer 7 may be made of amorphous silicon (α-Si) or polycrystalline silicon (p-Si), which is not limited herein. Alternatively, the semiconductor layer 7 may be made of indium gallium zinc oxide.

As shown in FIG. 1, the electrode layer 6 may be disposed on/above the substrate 1 of the above-mentioned photo-detector. The above semiconductor layer 7 may be disposed at a side of the electrode layer 6 away from the substrate 1. The photo-detector may further include a reading transistor 2 which is disposed on/above the substrate 1. The electrode layer 6 may be disposed at a side of the reading transistor 2 away from the substrate 1 and include a first electrode 601 and a second electrode 602. The first electrode 601 may be an induction electrode. The induction electrode is in electrical connection with a source electrode 206 or a drain electrode 205 of the reading transistor 2. The first electrode 601 may be made of metal such as molybdenum or aluminium, which is not limited in the embodiments of the present disclosure. The second electrode 602 may be a high voltage electrode in electrical connection with a bias signal line. An electric field may be formed between the second electrode 602 and the first electrode 601 such that the photo-generated carriers generated by the semiconductor layer 7 can form an electric current. Since the source electrode 206 or the drain electrode 205 of the above reading transistor is in electrical connection with the first electrode 601, the reading transistor 2 may read electric current formed by the photo-generated carriers through the first electrode 601. The second electrode 602 may be made of metal such as molybdenum or aluminium, which is not limited in the embodiments of the present disclosure. The second electrode 602 and the first electrode 601 both may be made of metal so that the first electrode 601, the second electrode 602 and the semiconductor layer to form a metal-semiconductor-metal photodiode. For example, the first electrode 601 and the second electrode 602 are made of a same material, aluminium. As shown in FIG. 2, the second electrode 602 may a closed annular structure. The second electrode 602 and the first electrode 601 may be spaced apart, and the second electrode 602 may surround the first electrode 601 to form an annular space between the first electrode 601 and the second electrode 602.

As shown in FIGS. 1, 2 and 3, the orthogonal projection of the first electrode 601 on the substrate 1 is referred to as a first projection and the orthogonal projection of the second electrode 602 on the substrate 1 is referred to as a second projection in the present disclosure. Since the annular space is formed between the first electrode 601 and the second electrode 602, an annular region 603 is formed between the first projection and the second projection. The annular region 603 has an inner edge and an outer edge. The inner edge of the annular region 603 is an outer edge of the first projection and the outer edge of the annular region 603 is an inner edge of the second projection. In the present disclosure, the inner edge of the annular region 603 is referred to as a first edge 6031, and the outer edge of the annular region 603 is referred to as a second edge 6032.

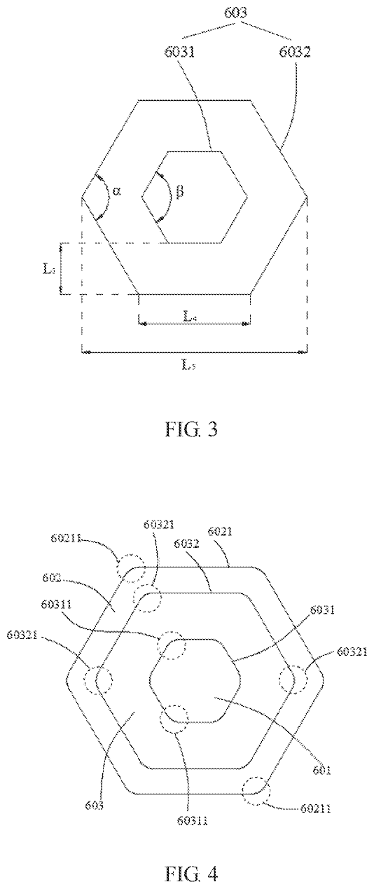

As shown in FIGS. 2 and 3, the first edge 6031 is closed and polygonal. In the present disclosure, each side of the first edge 6031 is referred to as a first side, that is, if the first edge 6031 has six sides, the first edge 6031 has six first sides. An included angle β of any two adjacent sides of the first edge 6031 is an obtuse angle, that is, an included angle β of any two adjacent first sides is an obtuse angle. Thus, the number of the first sides is at least 5, for example, 5, 6, 7, 8 and the like. As shown in FIG. 7, the first edge 6031 may also be circular in other embodiments of the present disclosure.

As shown in FIGS. 2 and 3, the second edge 6032 is also closed and polygonal. In the present disclosure, each side of the second edge 6032 is referred to as a second side, that is, if the second edge 6032 has six sides, the second edge 6032 has six second sides. An included angle α of any two adjacent sides of the second edge 6032 is an obtuse angle, that is, an included angle α of any two adjacent second sides is an obtuse angle. Thus, the number of the second sides is at least 5, for example, 5, 6, 7, 8 and the like. As shown in FIG. 7, the second edge 6032 may also be circular in other embodiments of the present disclosure. A center of circle of the circular second edge 6032 is overlapped with a center of circle of the circular first edge 6031.

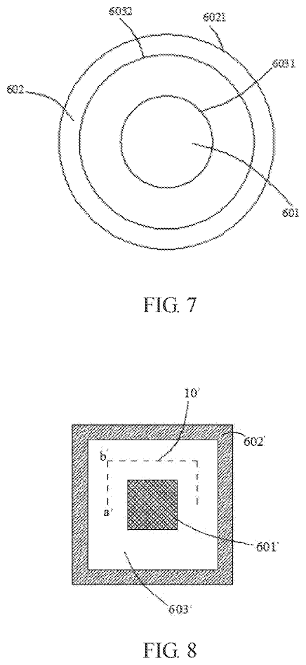

In the related art, as shown in FIG. 8, an inner edge and an outer edge of an annular region 603′ between a projection of the first electrode 601′ and a projection of a second electrode 602′ are square. In this case, as shown in FIG. 8, an electric field intensity at point a′ of a middle line 10′ of the annular region 603′ differs greatly from an electric field intensity at point b′ of the middle line 10′ of the annular region 603′.

For example, as shown in FIGS. 2 and 3, the first edge 6031 and the second edge 6032 both are polygonal. Since the numbers of the first sides and the second sides in the embodiment of the present disclosure both are equal to or greater than 5, the distance between the first edge 6031 and the second edge 6032 becomes more uniform and the electric field intensity between the first electrode 601 and the second electrode 602 becomes more uniform. An electric field intensity at point a of a middle line 10 of the annular region 603 differs relatively less from an electric field intensity at point b of the middle line 10 of the annular region 603, thereby improving the uniformity of the electric field intensity. In a further embodiment, the sides of the first edge 6031 and the sides of the second edge 6032 are identical in number and are parallel one-to-one, that is, the first sides are identical in number to the second sides, and a plurality of first sides and a plurality of second sides are in one-to-one parallel correspondence. In a further embodiment, as shown in FIG. 3, a distance L₁ between any first side and any second side which are in parallel correspondence may be equal. For example, the number of the first sides and the number of the second sides both are equal to 6, that is, the first edge 6031 and the second edge 6032 both are hexagonal.

Further, for example, as shown in FIG. 4, the first edge 6031 is polygonal. A connection of two adjacent sides of the first edge 6031 has a first rounded corner, that is, two adjacent first sides are joined by a first rounded corner, so as to improve smoothness of the first edge 6031 and make the electric field intensity between the first electrode 601 and the second electrode 602 more uniform. In a further embodiment, the connection of any two adjacent sides of the first edge 6031 has the first rounded corner. Curvature radii of a plurality of first rounded corners may be same or different. The curvature radius of the first rounded corner may be equal to or greater than 3 μm, which is not limited herein. Taking the second edge 6032 being a polygon as an example, a connection of two adjacent sides of the second edge 6032 has a second rounded corner, that is, two adjacent second sides are joined by a second rounded corner, so as to improve smoothness of the second edge 6032 and make the electric field intensity between the first electrode 601 and the second electrode 602 more uniform. In a further embodiment, the connection of any two adjacent sides of the second edge 6032 has the second rounded corner. Curvature radii of a plurality of second rounded corners may be same or different.

For example, as shown in FIG. 4, the above first sides are identical to the second sides in number, and a plurality of first sides are in one-to-one parallel correspondence with a plurality of second sides. The first edge 6031 has one first rounded corner, the second edge 6032 has one second rounded corner, two first sides joined by the first rounded corner are in one-to-one parallel correspondence with two second sides joined by the second rounded corner, and a center of circle of the first rounded corner is overlapped with a center of circle of the second rounded corner. In another embodiment, the above first sides are identical to the second sides in number, and a plurality of first sides are in one-to-one parallel correspondence with a plurality of second sides. Any two adjacent sides of the first edge 6031 have a first rounded corner 60311, and any two adjacent sides of the second edge 6032 has a second rounded corner 60321. A plurality of first rounded corners are in one-to-one correspondence with a plurality of second rounded corners, and a center of circle of any first rounded corner is overlapped with a center of circle of the corresponding second rounded corner.

Furthermore, as shown in FIGS. 2 and 4, an outer edge of the orthogonal projection of the second electrode 602 on the substrate 1 is closed, that is, the outer edge of the above-mentioned second projection is closed and polygonal. In the present disclosure, the outer edge of the second projection is referred to as a third edge 6021 and each side of the third edge 6021 is referred to as a third side. If the third edge 6021 has six sides, the third edge 6021 has six third sides. The third edge 6021 may be polygonal and an included angle of any two adjacent sides is an obtuse angle, that is, an included angle of any two adjacent third sides is an obtuse angle. Thus, the number of the third sides is equal to or greater than 5, for example, 5, 6, 7, 8 and the like. Since the numbers of the third sides and the second sides both are equal to or greater than 5, a distance between the third edge 6021 and the second edge 6032 is more uniform, that is, the annular second electrode 602 is more uniform in radial thickness. Furthermore, the third sides are identical to the second sides in number, and a plurality of third sides are in one-to-one parallel correspondence with a plurality of second sides. A distance L₂ between any second side and any third side in parallel correspondence may be same. For example, the number of the third sides and the number of the second sides both are 6. A third rounded corner is formed at a connection of two adjacent sides of the third edge 6021 such that the distance between the third edge 6021 and the second edge 6032 is made more uniform. A center of circle of the third rounded corner is overlapped with a center of circle of the above second rounded corner. In a further embodiment, a third rounded corner 60211 is formed at the connection of any two adjacent sides of the third edge 6021. In a further example, the center of circle of the first rounded corner(s), the center of circle of the second rounded corner(s) and the center of circle of the third rounded corner(s) are overlapped, and an angle of the first rounded corner may be 22°-35°, which is not limited in this embodiment of the present disclosure. As shown in FIG. 7, the third edge 6021 may be circular in other embodiments of the present disclosure. The center of circle of the circular third edge 6021 is overlapped with the center of circle of the circular second edge 6032.

As shown in FIGS. 2 and 3, in an embodiment of the present disclosure, the first edge 6031, the second edge 6032 and the third edge 6021 all are hexagonal, a distance L₃ of two opposed third sides may be equal to 30 μm, a distance L₁ of the first side and the second side in parallel correspondence may be equal to 7 μm, and a distance L₂ of the second side and the third side in parallel correspondence may be equal to 4 μm. A difference of a distance L₅ between two opposed vertices of the second edge 6032 and a length L₄ of the second side of the second edge 6032 (L₅−L₄) may be 88*h % μm, where h may be 3.33, 6.67, 10.00, 13.33, 16.67, 20.00 or 23.33. Correspondingly, an effective area S of the electric field between the first electrode 601 and the second electrode 602 is as shown in Table 1.

TABLE 1

| h | 3.33 | 6.67 | 10.00 | 13.33 | 16.67 | 20.00 | 23.33 |
|---|---|---|---|---|---|---|---|
| S/μm² | 486.1 | 491.7 | 495.1 | 496.6 | 496.3 | 494.6 | 491.7 |

In a photodiode in the related art as shown in FIG. 8, the inner edge and the outer edge of the annular region 603′ between the projection of the first electrode 601′ and the projection of the second electrode 602′ both are square. A side length of outer edge of the annular region 603′ is 22 μm and a side length of the inner edge of the annular region 603′ is 7 μm. The distance between the inner edge and the outer edge of the projection of the second electrode 602′ is equal to L₂, i.e. 4 μm. An outer edge of the projection of the second electrode 602′ is also a square with a side length being L₃, i.e. 30 μm. The effective area of the electric field between the first electrode 601′ and the second electrode 602′ in the related art as shown in FIG. 8 is calculated as 477.9 μm² which is smaller than the effective area of each electric field in Table 1. Therefore, in the embodiments of the present disclosure, the effective area of the electric field between the first electrode and the second electrode is increased.

The present disclosure further provides a photo-detector. As shown in FIG. 1, the photo-detector may include the photodiode in any above embodiment and a substrate 1. The electrode layer 6 of the photodiode is disposed on the substrate 1.

The photodiode included in the photo-detector according to this embodiment of the present disclosure is identical to the photodiode in the above photodiode embodiments and thus has the same beneficial effect. Therefore, no redundant descriptions will be made herein.

As shown in FIG. 1, the substrate 1 may be a glass substrate or a silicon wafer, which is not limited in the present disclosure. The substrate 1 may alternatively be a polyimide plastic substrate or the like. In the present disclosure, the photo-detector may further include a reading transistor 2 which is disposed on the substrate 1. The reading transistor 2 may include a gate electrode 201, a gate insulation layer 202, an active layer 203, an inter-layer insulation layer 204, a source electrode 206 and a drain electrode 205. The gate electrode 201 is disposed on the substrate 1. The gate insulation layer 202 is disposed at a side of the gate electrode 201 away from the substrate 1. The active layer 203 is disposed at a side of the gate insulation layer 202 away from the substrate 1. The active layer 203 may include a non-doped channel region, a source region and drain region. The inter-layer insulation layer 204 may cover the active layer 203 and the gate insulation layer 202. The source electrode 206 and the drain electrode 205 may be disposed on the inter-layer insulation layer 204 and penetrated through vias in the inter-layer insulation layer 204 to couple to the source region and the drain region of the active layer 203. Further, a plurality of reading transistors 2 may be disposed on the substrate 1. In addition, the photo-detector of the present disclosure may further include a wire 8. The wire 8 may be a data line or a gate line, which is not limited herein.

As shown in FIG. 1, the photo-detector of the present disclosure may further include a first planarization layer 3, a blocking metal layer 4 and a second planarization layer 5. The first planarization layer 3 may cover the source electrode 206, the drain electrode 205 and the inter-layer insulation layer 204 of the reading transistor 2. The blocking metal layer 4 may be disposed on the first planarization layer 3. The blocking metal layer 4 may include a plurality of blocking metal regions. A part of the blocking metal regions is used to cover the active layer 203 of the reading transistor 2 to block light from irradiating on the active layer 203 of the reading transistor 2. A part of the blocking metal regions is penetrated through a via in the first planarization layer 3 to electrically connect with the source electrode 206 or the drain electrode 205 of the reading transistor 2 and blocks light from irradiating on the source electrode 206 or the drain electrode 205 of the reading transistor 2. The second planarization layer 5 may cover the blocking metal layer and the first planarization layer 3.

As shown in FIG. 1, the electrode layer 6 of the above photodiode may be disposed at a side of the second planarization layer 5 away from the first planarization layer 3. The first electrode 601 in the electrode layer 6 may be penetrated through a via in the second planarization layer 5 to electrically connect with the blocking metal layer 4 in electrical connection with the source electrode 206 or the drain electrode 205 of the reading transistor 2, such that the first electrode 601 is electrically connected with the source electrode 206 or the drain electrode 205 of the reading transistor 2. A plurality of photodiodes may be disposed and the plurality of photodiodes are in one-to-one correspondence with a plurality of reading transistors 2. Second electrodes 602 of any two adjacent photodiodes in a plurality of photodiodes may be electrically connected, thereby reducing the number of bias signal lines in electrical connection with the second electrodes 602 and simplifying the structure of the photo-detectors. The semiconductor layers 7 of a plurality of photodiodes may be of an integral structure, that is, the semiconductor layers 7 of a plurality of photodiodes are integrated into one film layer, thus simplifying the steps of forming the semiconductor layer 7. The photo-detector according to the embodiments of the present disclosure may further include a scintillation layer which is disposed at a side of the semiconductor layer 7 away from the substrate 1. The scintillation layer may convert X rays into visible light for absorption by the semiconductor layer 7.

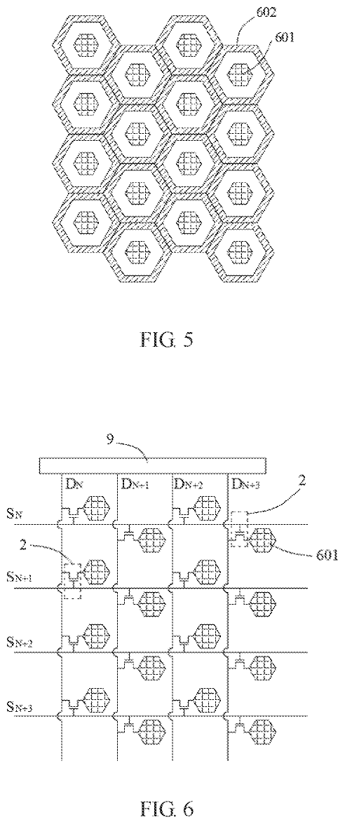

Furthermore, as shown in FIG. 5, for example, there are a plurality of photodiodes and the outer edges of the orthogonal projections of the second electrodes 602 on the substrate 1 are hexagonal. The orthogonal projections of the second electrodes 602 of the plurality of photodiodes on the substrate 1 are arranged like honeycomb, that is, the plurality of photodiodes are hexagonal close packed so as to improve a density of the photodiodes. As shown in FIG. 6, when a plurality of photodiodes are hexagonal close packed, the first electrodes 601 in the plurality of photodiodes are in one-to-one corresponding connection with a plurality of reading transistors 2. A gate line S_{N}, a gate line S_{N+1}, a gate line S_{N+2} and a gate line S_{N+3} provide scanning signals line by line, the reading transistors 2 are turned on line by line, and electrical signals generated by the photodiodes are sent to a chip 9 through a data line D_{N}, a data line D_{N+1}, a data line D_{N+2} and a data line D_{N+3}. The chip 9 may include a signal amplifying and reading circuit. The signal amplifying and reading circuit may obtain digital signals by performing amplification and analog to digital conversion and the like for the electrical signals and then transmit the digital signals to an image processing system of a computer for imaging. In order to avoid image distortion, the (N+1)-th column of photodiodes and the (N+3)-th column of photodiodes maintain invariable outputs, an output of the N-th column of photodiodes may be (P_{NN}+P_{NN+1})/2 and an output of the (N+2)-th column of photodiodes may be (P_{NN+2}+P_{N+1N+2})/2, where P_{NN} is an output signal of the photodiode of row N and column N. P_{NN+1} is an output signal of the photodiode of row N and column (N+1), P_{NN+2} is an output signal of the photodiode of row N and column (N+2), and P_{N+1N+2} is an output signal of the photodiode of row (N+1) and column (N+2).

The present disclosure further provides an imaging system. The imaging system may include the photo-detector(s) according to any one of the above embodiments. Of course, the imaging system may further include a display. The display may be connected with the photo-detector to form a display image based on signals generated by the photo-detector(s). Because the photo-detector included in the imaging system is identical to the photo-detector in the above photo-detector embodiments and has the same beneficial effect, no redundant descriptions are made herein.

The above descriptions are merely preferred embodiments of the present disclosure rather than intended to limit the present disclosure in any manner. Although the present disclosure is made with preferred embodiments as above, these preferred embodiments are not used to limit the present disclosure. Those skilled in the art may make some changes or modifications to the technical contents of the present disclosure without departing from the scope of the technical solution of the present disclosure. Any simple changes, equivalent changes or modifications made to the above embodiments based on the technical essence of the present disclosure without departing from the contents of the technical solution of the present disclosure shall all fall within the scope of protection of the present disclosure.

What is claimed is:

1. A photodiode, comprising:
an electrode layer, comprising a first electrode and a second electrode surrounding the first electrode, wherein an annular region between an orthogonal projection of the second electrode on a substrate and an orthogonal projection of the first electrode on the substrate has an inner edge and an outer edge; the inner edge of the annular region is polygonal or circular, and an included angle of any two adjacent sides of the inner edge of the annular region is an obtuse angle when the inner edge of the annular region is polygonal; the outer edge of the annular region is polygonal or circular, and an included angle of any two adjacent sides of the outer edge of the annular region is an obtuse angle when the outer edge of the annular region is polygonal, and
a semiconductor layer, disposed at a side of the electrode layer away from the substrate.

2. The photodiode according to claim 1, wherein the inner edge and the outer edge of the annular region both are polygonal, and the sides of the inner edge of the annular region and the sides of the outer edge of the annular region are identical in number and are parallel one-to-one.

3. The photodiode according to claim 1, wherein
the inner edge of the annular region is polygonal, and a first rounded corner is formed at a connection of two adjacent sides of the inner edge of the annular region; and/or,
the outer edge of the annular region is polygonal, and a second rounded corner is formed at a connection of two adjacent sides of the outer edge of the annular region.

4. The photodiode according to claim 2, wherein
a connection of two adjacent sides of the inner edge of the annular region has a first rounded corner, a connection of two sides of the outer edge of the annular region parallel with the two adjacent sides of the inner edge of the annular region has a second rounded corner, and
a center of circle of the first rounded corner is overlapped with a center of circle of the second rounded corner.

5. The photodiode according to claim 2, wherein the inner edge and the outer edge of the annular region both are hexagonal.

6. The photodiode according to claim 1, wherein
an outer edge of the orthogonal projection of the second electrode on the substrate is polygonal and an included angle of any two adjacent sides is an obtuse angle; or,
the outer edge of the orthogonal projection of the second electrode on the substrate is circular.

7. The photodiode according to claim 6, wherein the outer edge of the orthogonal projection of the second electrode on the substrate is polygonal and a third rounded corner is formed at a connection of at least two adjacent sides of the outer edge of the orthogonal projection of the second electrode on the substrate.

8. The photodiode according to claim 6, wherein the outer edge of the orthogonal projection of the second electrode on the substrate is polygonal, the outer edge of the annular region is polygonal, and the sides of the outer edge of the orthogonal projection of the second electrode on the substrate and the sides of the outer edge of the annular region are identical in number and are parallel one-to-one.

9. The photodiode according to claim 6, wherein the outer edge of the orthogonal projection of the second electrode on the substrate is hexagonal.

10. A photo-detector, comprising:
a substrate; and
a photodiode, comprising:
an electrode layer, disposed on the substrate and comprising a first electrode and a second electrode surrounding the first electrode, wherein an annular region between an orthogonal projection of the second electrode on the substrate and an orthogonal projection of the first electrode on the substrate has an inner edge and an outer edge; the inner edge of the annular region is polygonal or circular, and an included angle of any two adjacent sides of the inner edge of the annular region is an obtuse angle when the inner edge of the annular region is polygonal; the outer edge of the annular region is polygonal or circular, and an included angle of any two adjacent sides of the outer edge of the annular region is an obtuse angle when the outer edge of the annular region is polygonal; and
a semiconductor layer, disposed at a side of the electrode layer away from the substrate.

11. The photo-detector according to claim 10, wherein the photodiode comprises a plurality of photodiodes and second electrodes of any two adjacent photodiodes are in electrical connection.

12. The photo-detector according to claim 10, wherein the photodiode comprises a plurality of photodiodes and the semi-conductor layers of the plurality of photodiodes are of an integral structure.

13. The photo-detector according to claim 10, further comprising:
a reading transistor, disposed on the substrate, wherein the electrode layer is disposed at a side of the reading transistor away from the substrate, and the first electrode is in electrical connection with a source electrode or a drain electrode of the reading transistor.

14. The photo-detector according to claim 10, wherein the photodiode comprises a plurality of photodiodes, and orthogonal projections of the second electrodes of the plurality of photodiodes on the substrate are arranged like honeycomb.

15. The photo-detector according to claim 10, wherein the inner edge and the outer edge of the annular region both are polygonal, and the sides of the inner edge of the annular region and the sides of the outer edge of the annular region are identical in number and are parallel one-to-one.

16. The photo-detector according to claim 10, wherein
the inner edge of the annular region is polygonal and a first rounded corner is formed at a connection of two adjacent sides of the inner edge of the annular region; and/or,
the outer edge of the annular region is polygonal, and a second rounded corner is formed at a connection of two adjacent sides of the outer edge of the annular region.

17. The photo-detector according to claim 15, wherein
a connection of two adjacent sides of the inner edge of the annular region has a first rounded corner, a connection of two sides of the outer edge of the annular region parallel with the two adjacent sides of the inner edge of the annular region has a second rounded corner, and
a center of circle of the first rounded corner is overlapped with a center of circle of the second rounded corner.

18. The photo-detector according to claim 10, wherein
an outer edge of the orthogonal projection of the second electrode on the substrate is polygonal and an included angle of any two adjacent sides is an obtuse angle; or,
the outer edge of the orthogonal projection of the second electrode on the substrate is circular.

19. The photo-detector according to claim 18, wherein the outer edge of the orthogonal projection of the second electrode on the substrate is polygonal, and a third rounded corner is formed at a connection of at least two adjacent sides of the outer edge of the orthogonal projection of the second electrode on the substrate.

20. An imaging system, comprising at least one photo-detector each comprising:
a substrate; and
a photodiode, comprising:
an electrode layer, disposed on the substrate and comprising a first electrode and a second electrode surrounding the first electrode, wherein an annular region between an orthogonal projection of the second electrode on the substrate and an orthogonal projection of the first electrode on the substrate has an inner edge and an outer edge; the inner edge of the annular region is polygonal or circular, and an included angle of any two adjacent sides of the inner edge of the annular region is an obtuse angle when the inner edge of the annular region is polygonal; the outer edge of the annular region is polygonal or circular, and an included angle of any two adjacent sides of the outer edge of the annular region is an obtuse angle when the outer edge of the annular region is polygonal; and
a semiconductor layer, disposed at a side of the electrode layer away from the substrate.
